(19) United States
(12) Patent Application Publication
(10) Pub. No.: US 2003/0141605 A1
(43) Pub. Date: Jul. 31, 2003

(54) Method of forming identifying mark on semiconductor wafer

(75) Inventors: Shyh-Dar Lee, Hsinchu Hsien (TW); Chen-Chiu Hsue, Hsinchu (TW)

Correspondence Address: Merchant & Gould P.C., P.O. Box 2903, Minneapolis, MN, 55402-0903, US

(73) Assignee: Silicon Integrated Systems Corp.

(21) Appl. No.: 10/191,157

(22) Filed: Jul. 9, 2002

(30) Foreign Application Priority Data
Jan. 25, 2002 (TW) 91101216

(51) Int. Cl. H01L 23/544

(52) U.S. Cl. 257/797

(57) ABSTRACT

A method of forming an identifying mark on a semiconductor wafer. The identifying mark, for example a bar code or a character of patterns or words, is formed on the side wall of the semiconductor wafer to avoid contamination and the creation of failure dies during the formation of the identifying mark.

### BACKGROUND OF THE INVENTION

1. Field of the Invention

The present invention relates in general to a process of manufacturing a semiconductor wafer. More particularly, it relates to a method of forming an identifying mark on a semiconductor wafer.

2. Description of the Related Art

As the number of devices that may be introduced into a single semiconductor chip increases, the time of the manufacturing process is lengthened, while the layout of the integration circuits (ICs) becomes more complicated. In the manufacture of semiconductor chips, a wafer of silicon or other semiconductor material is processed to form the individual chips. After repeating a series of cleaning, oxidizing, depositing, lithography, etching, and implantation process, a semiconductor wafer still needs to be electrically tested and covered by a passivation layer. More than one month is require to manufacture a semiconductor chip. Therefore, it is very important to identify individual wafers during the manufacturing process.

In the prior art, a character of patterns or words is laser-scribed as an identifying mark in the rim II of the top face of a semiconductor wafer 10, as shown in FIG. 1. The semiconductor wafer 10 is processed sequentially for the manufacture of integrated circuits (ICs) 12 on the semiconductor wafer 10. FIG. 2 is a schematic magnified drawing of the identifying mark of FIG. 1. The number 15 is the identifying mark, XYZ-001.

There are several disadvantages to using the laser-scribed identifying mark of the prior art. One of the disadvantages is the decrease of the available areas due to the creation of failure dies during the process of forming the identifying mark 15. Another disadvantage is the contamination problem. Some particles are formed on the surface of the semiconductor wafer 10 when the character of the identifying mark 15 is formed by a laser beam. It is difficult to remove the particles from the surface of the semiconductor wafer 10. In following process, the semiconductor wafer 10 is fixed by a clamp. The particles are spread over the surface of the semiconductor wafer 10 during the clamp is released. Therefore, the electric character of ICs is damaged. Additionally, the identifying mark 15 is usually disappear during the planarization processes, such as chemical mechanical polish, because the identifying mark 15 is placed on the top face of the semiconductor wafer 10.

### SUMMARY OF THE INVENTION

Therefore, an object of the present invention to provide a method of forming an identifying mark on a semiconductor wafer that substantially obviates the above-mentioned problems.

An object of the present invention is to provide a method of forming an identifying mark on a semiconductor wafer without damaging the wafer and creating failure dies.

Another object of the present invention is to provide a method of forming an identifying mark on a semiconductor wafer that overcomes the problem of contamination dues to the particles during its manufacture.

A further object of the present invention is to provide a method of forming an identifying mark on a semiconductor wafer, so as to maintain the integrity of the identifying mark during following manufacturing processes.

To achieve the above-mentioned objects, the method of the present invention comprises the following steps. First, a semiconductor wafer comprising a top face, a reverse face, and a side wall is provided. The side wall comprises a flat face and an arc face. Next, an identifying mark is formed on the side wall of the semiconductor. The identifying mark is preferably formed by etching or laser-scribing.

According to an aspect of the invention, the identifying mark comprises a character of patterns or words. The character comprising small dots can be seen by human eye.

According to another aspect of the invention, the identifying mark comprises a bar code made up of trenches. The laser-scribed identifying mark can be read by a machine.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIG. 1 is a schematic top-view drawing illustrating the identifying mark on a semiconductor in the prior art.

FIG. 2 is a magnified drawing of parts of FIG. 1.

FIG. 3 is a schematic three-dimensional picture of a semiconductor wafer.

FIG. 4 is a schematic side view drawing of the flat face of a semiconductor wafer showing an identifying mark.

FIG. 5 is a schematic side view drawing of the flat face of a semiconductor wafer showing a second type of identifying mark.

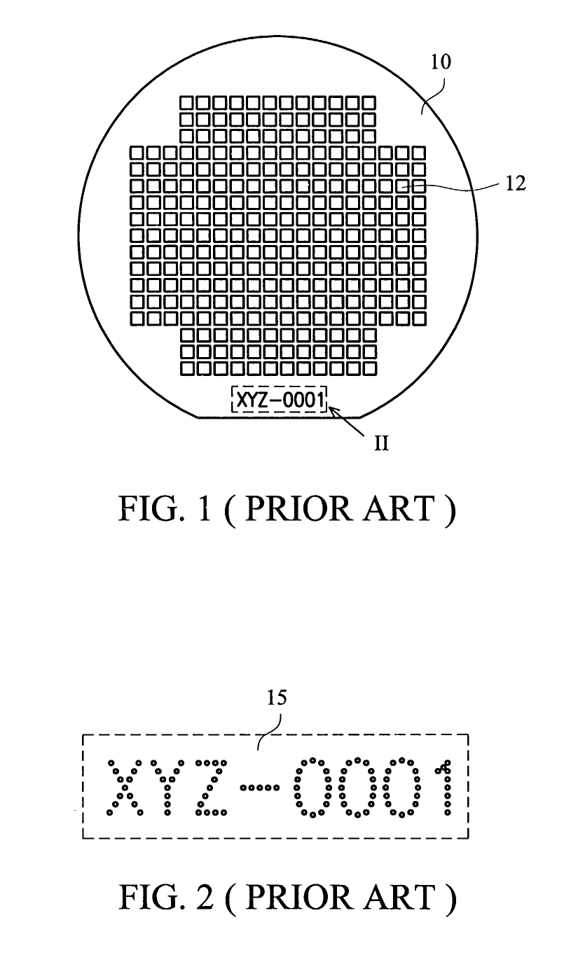

### DETAILED DESCRIPTION OF THE PREFERRED EMBODIMENT

There will now be described an embodiment of this invention with reference to the accompanying drawings.

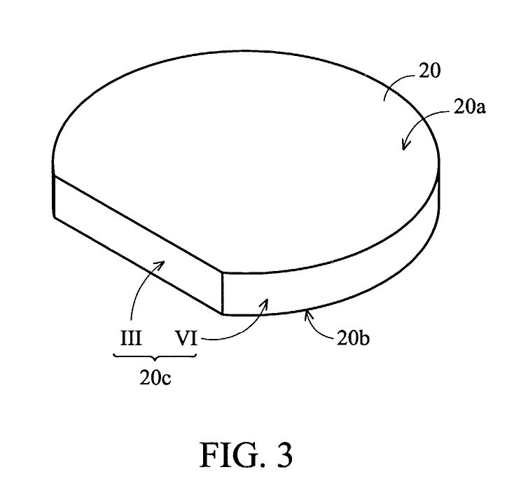

First, a semiconductor wafer 20, having a top face 20a, a reverse face 20b, and a side wall 20c, is provided, as shown in FIG. 3. The side wall 20c comprises a flat face III and an arc face VI.

Next, an identifying mark is formed on the side wall 20c. The identifying mark is placed either on the flat face III or the arc face VI. The identifying mark can be formed by conventional etching or laser-scribing.

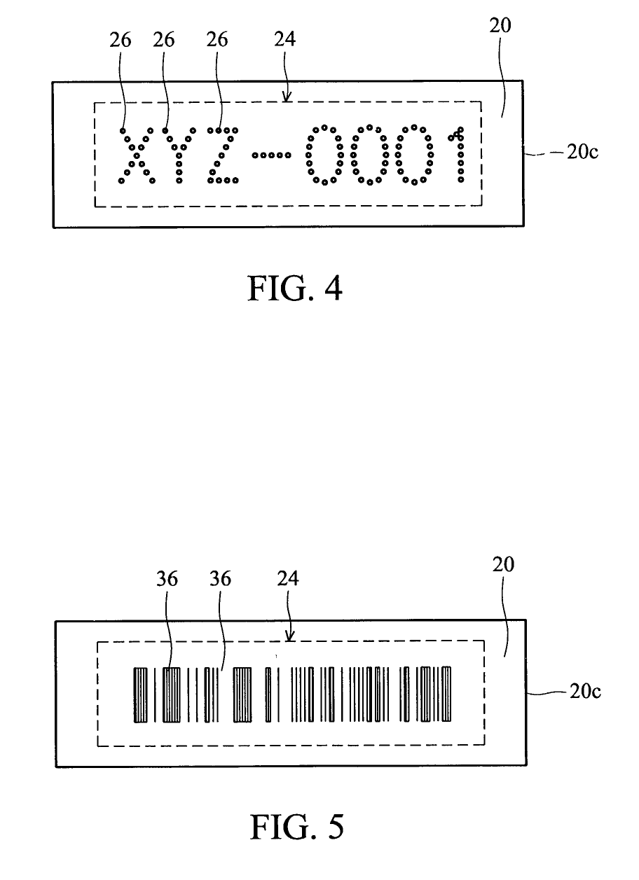

In one embodiment of the present invention, the identifying mark 24 is a character consisting of a plurality of small dots 26, as shown in FIG. 4. For example, XYZ-001 is the identifying mark 24 on the side wall 20c of the semiconductor wafer 20. The identifying mark 24 can either be read directly by human eye or identified by a machine apparatus after magnification.

In another embodiment of the present invention, the identifying mark 24 is a bar code consisting of a plurality of trenches 36, as shown in FIG. 5. The identifying mark 24 can be detected by a machine apparatus.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of forming an identifying mark on a semiconductor wafer, comprising:
providing a semiconductor wafer comprising a top face, a reverse face, and a side wall;
forming an identifying mark on the side wall of the semiconductor.

2. The method as claimed in claim 1, wherein the identifying mark comprises a character of patterns or words.

3. The method as claimed in claim 2, wherein the character comprises small dots.

4. The method as claimed in claim 1, wherein the identifying mark comprises a bar code.

5. The method as claimed in claim 4, wherein the bar code comprises trenches.

8. The method as claimed in claim 1, wherein the identifying mark is laser-scribed.

9. The method as claimed in claim 1, wherein the identifying mark is formed by etching.

10. The method as claimed in claim 9, wherein the side wall comprises a flat face and an arc face.
